(19) United States
(12) Patent Application Publication
(10) Pub. No.: US 2024/0036672 A1
(43) Pub. Date: Feb. 1, 2024

(54) DISPLAY DEVICE

(71) Applicant: Samsung Display Co., Ltd., Yongin-si (KR)

(72) Inventors: CHANG-WOO SHIM, Yongin-si (KR); Juyeon KIM, Yongin-si (KR); WONSANG PARK, Yongin-si (KR); GI-NA YOO, Yongin-si (KR); SEONGJUN LEE, Yongin-si (KR); SANGHYUN JUN, Yongin-si (KR)

(21) Appl. No.: 18/309,561

(22) Filed: Apr. 28, 2023

(30) Foreign Application Priority Data
Jul. 28, 2022 (KR) 10-2022-0094210

(51) Int. Cl. G06F 3/041; H10K 59/122; H10K 59/38; H10K 59/40; H10K 59/80; G06F 3/03

(52) U.S. Cl. CPC G06F 3/0412; H10K 59/122; H10K 59/38; H10K 59/40; H10K 59/8792; G06F 3/0317; G06F 3/03545

(57) ABSTRACT

A display device includes: a light-emitting element including a first electrode, a second electrode on the first electrode, and a light-emitting layer between the first electrode and the second electrode; a pixel-defining film having a pixel opening exposing the first electrode; a sensing electrode on the pixel-defining film; a light-blocking pattern on the sensing electrode; and a color filter on the sensing electrode, wherein the light-blocking pattern comprises a first pattern part and a second pattern part, and the first pattern part and the second pattern part have different optical densities (OD) with respect to first light.

### CROSS-REFERENCE TO RELATED APPLICATIONS

The present patent application claims priority to and the benefit of Korean Patent Application No. 10-2022-0094210, filed on Jul. 28, 2022, the entire content of which is incorporated herein by reference.

### BACKGROUND

### 1. Field

Aspects of some embodiments of the present disclosure herein relate to a display device.

### 2. Description of the Related Art

With the development of an information-oriented society, demands for a display device for displaying images are increasing in various forms. For example, a display device is applied to various electronic devices such as a smart phone, a digital camera, a laptop computer, a navigation system, and a smart television. A recent display device supports a touch input using a part of a user's body (for example, a finger) and a touch input using an electronic pen. A display device senses a touch input using an electronic pen, and may thus sense a touch input more minutely than when using only a touch input using a part of a user's body.

There are electronic pens which may be driven in various ways, and an optical electronic pen thereamong may generate light having a predetermined wavelength range. A display device using the optical electronic pen may include a code which is recognized by the optical electronic pen. The code may include a material such as carbon, but a solution to prevent or reduce visibility of the code from the outside of the display device may be desired.

The above information disclosed in this Background section is only for enhancement of understanding of the background and therefore the information discussed in this Background section does not necessarily constitute prior art.

### SUMMARY

Aspects of some embodiments of the present disclosure herein relate to a display device, and for example, to a display device including a light-blocking pattern on a sensing electrode.

Aspects of some embodiments of the present disclosure include a display device capable of preventing or reducing visibility of a light-blocking pattern from the outside.

According to some embodiments of the inventive concept, a display device including a light-emitting element including a first electrode, a second electrode on the first electrode, and a light-emitting layer between the first electrode and the second electrode, a pixel-defining film in which a pixel opening exposing the first electrode is defined, a sensing electrode on the pixel-defining film, a light-blocking pattern on the sensing electrode, and a color filter on the sensing electrode, wherein the light-blocking pattern includes a first pattern part and a second pattern part, and the first pattern part and the second pattern part have different optical densities (OD) with respect to first light.

According to some embodiments, the first light may have a wavelength range of about 800 nm to about 1000 nm. According to some embodiments, the first pattern part may have an optical density of about 1 or more with respect to light having a wavelength range of about 800 nm to about 1000 nm, and the second pattern part may have an optical density of less than about 1 with respect to light having a wavelength range of about 800 nm to about 1000 nm.

According to some embodiments, the sensing electrode may include a conductive line defining an electrode opening corresponding to the light-emitting element, and the first pattern part may be in contact with an upper surface and a side surface of a first part of the conductive line.

According to some embodiments, the first pattern part may include a first region in contact with the upper surface and a second region in contact with the side surface, and a first length of the first region in a normal direction of the upper surface may be shorter than a second length of the second region in a normal direction of the side surface.

According to some embodiments, a width of the electrode opening may be greater than a width of the pixel opening in a direction perpendicular to a thickness direction.

According to some embodiments, the second pattern part may be on the first pattern part.

According to some embodiments, on a cross-section, the first pattern part and the second pattern part may be spaced apart from each other.

According to some embodiments, the first pattern part and the second pattern part may each include an infrared reactive material that absorbs light having a wavelength range of about 800 nm to about 1000 nm.

According to some embodiments, a first content of the infrared reactive material with respect to the total weight of the first pattern part may be greater than a second content of the infrared reactive material with respect to the total weight of the second pattern part.

According to some embodiments, the infrared reactive material may include carbon.

According to some embodiments, the infrared reactive material may further include silicon.

According to some embodiments, the light-emitting element may include a first light-emitting element emitting first color-light, a second light-emitting element emitting second color-light different from the first color-light, and a third light-emitting element emitting third color-light different from the first color-light and the second color-light, and the color filter may include a first filter transmitting the first color-light, a second filter transmitting the second color-light, and a third filter transmitting the third color-light.

According to some embodiments, on the first pattern part, at least two filters among the first filter, the second filter, and the third filter overlap each other.

According to some embodiments of the inventive concept, a display device includes a light-emitting element including a first electrode, a second electrode on the first electrode, and a light-emitting layer between the first electrode and the second electrode, a pixel-defining film in which a pixel opening exposing the first electrode is defined, a sensing electrode on the pixel-defining film, a light-blocking pattern on the sensing electrode, and a color filter on the sensing electrode, and overlapping the light-emitting element, wherein the sensing electrode includes a conductive line defining an electrode opening corresponding to the light-emitting element, and the light-blocking pattern includes a third pattern part overlapping a first part of the conductive line and having a first width, and a fourth pattern part overlapping a second part of the conductive line and having a second width smaller than the first width.

According to some embodiments, the light-blocking pattern may have an optical density (OD) of about 1 or more with respect to light having a wavelength range of about 800 nm to about 1000 nm.

According to some embodiments, on a plane, the third pattern part and the fourth pattern part may each extend in a first extension direction and in a second extension direction crossing the first extension direction, and the first width and the second width may be each parallel to any one of the first extension direction and the second extension direction.

According to some embodiments, a width of the pixel-defining film may be greater than the second width in a direction perpendicular to a thickness direction.

According to some embodiments, on a cross-section, the third pattern part and the fourth pattern part may be spaced apart from each other.

According to some embodiments, the display device may be divided into a light-emitting region corresponding to the pixel opening and a non-light-emitting region surrounding the light-emitting region, the light-emitting region may include first light-emitting regions emitting first color-light, second light-emitting regions emitting second color-light different from the first color-light, and third light-emitting regions emitting third color-light different from the first color-light and the second color-light, and on a cross-section, the third pattern part may surround one first light-emitting region, two second light-emitting regions, and one third light-emitting region.

According to some embodiments, the third pattern part may overlap the non-light-emitting regions between the one first light-emitting region, the two second light-emitting regions, and the one third light-emitting region.

According to some embodiments, on a plane, the fourth pattern part may extend from an edge of the third pattern part.

According to some embodiments, the third pattern part and the fourth pattern part may each include an infrared reactive material that absorbs light having a wavelength range of about 800 nm to about 1000 nm.

According to some embodiments, the infrared reactive material may include carbon.

According to some embodiments, the infrared reactive material may further include silicon.

### BRIEF DESCRIPTION OF THE DRAWINGS

The accompanying drawings are included to provide a further understanding of the inventive concept, and are incorporated in and constitute a part of this specification. The drawings illustrate aspects of some embodiments of the inventive concept and, together with the description, serve to explain principles of the inventive concept. In the drawings:

FIG. 1 is a perspective view illustrating a display device according to some embodiments;

FIG. 2 is an exploded perspective view illustrating a display device according to some embodiments;

FIG. 3 is a cross-sectional view illustrating a part corresponding to the line X-X′ in FIG. 2;

FIG. 4 is a plan view illustrating a part of a display device according to some embodiments;

FIG. 5 is an enlarged plan view of region AA′ in FIG. 4;

FIG. 6 is a cross-sectional view illustrating a part corresponding to the line I-I′ in FIG. 4;

FIG. 7 is an enlarged cross-sectional view of region BB′ in FIG. 6;

FIG. 8 is a plan view illustrating a part of a display device according to some embodiments;

FIG. 9 is a cross-sectional view illustrating a part corresponding to the line II-II′ in FIG. 8;

FIG. 10 is a plan view illustrating a part of a display device according to some embodiments;

FIG. 11 is a plan view illustrating a part of a display device according to some embodiments;

FIG. 12 is a cross-sectional view illustrating a part corresponding to the line III-Ill′ in FIG. 11;

FIG. 13 is a perspective view illustrating a display device and a touch input device according to some embodiments; and

FIG. 14 is a block diagram illustrating a display device and a touch input device according to some embodiments.

### DETAILED DESCRIPTION

In the inventive concept, various modifications may be made and various forms may be applied, and specific embodiments will be illustrated in the drawings and described in detail in the text. However, this is not intended to limit the inventive concept to a specific disclosure form, it should be understood to include all changes, equivalents, and substitutes included in the spirit and scope of the inventive concept.

In this specification, when a component (or region, layer, portion, etc.) is referred to as “on”, “connected”, or “coupled” to another component, it means that it is placed/connected/coupled directly on the other component or a third component can be located between them.

The same reference numerals or symbols refer to the same elements. In addition, in the drawings, thicknesses, ratios, and dimensions of components are exaggerated for effective description of technical content. “And/or” includes all combinations of one or more that the associated elements may define.

Terms such as first and second may be used to describe various components, but the components should not be limited by the terms. These terms are only used for the purpose of distinguishing one component from other components. For example, without departing from the scope of the present invention, a first component may be referred to as a second component, and similarly, a second component may be referred to as a first component. Singular expressions include plural expressions unless the context clearly indicates otherwise.

In addition, terms such as “below”, “lower”, “above”, and “upper” are used to describe the relationship between components shown in the drawings. The terms are relative concepts and are described based on the directions indicated in the drawings.

Terms such as “include” or “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

Unless otherwise defined, all terms (including technical and scientific terms) used in this specification have the same meaning as commonly understood by one of ordinary skill in the art to which this invention belongs. In addition, terms such as terms defined in commonly used dictionaries should be interpreted as having a meaning consistent with the meaning having in the context of the related technology, and should not be interpreted as too ideal or too formal unless explicitly defined here.

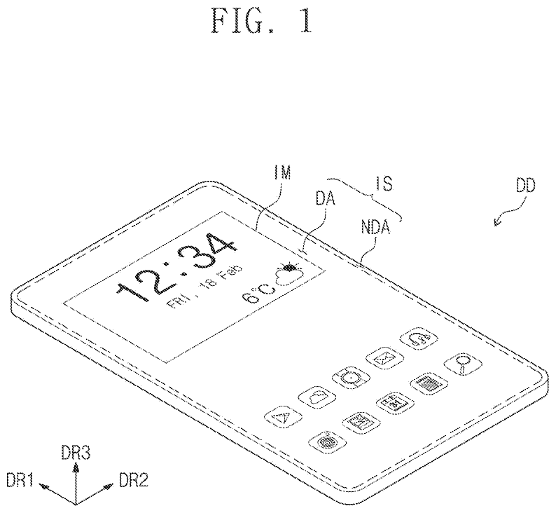

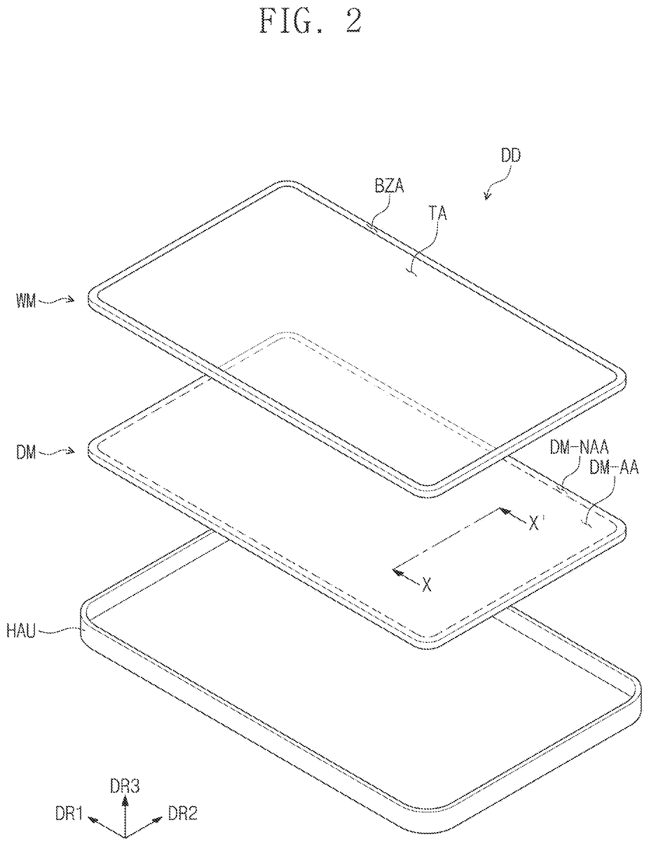

Hereinafter, a display device according to some embodiments will be described with reference to the drawings. FIG. 1 is a perspective view illustrating a display device DD according to some embodiments. FIG. 2 is an exploded perspective view of the display device DD according to some embodiments.

The display device DD according to some embodiments may be activated in response to an electrical signal. For example, the display device DD may be applied to not only a large-sized electronic device such as a television or a monitor, but also a small- and medium-sized electronic device such as a portable electronic device, a tablet computer, a car navigation, a game console, a laptop computer, or a wearable device. FIG. 1 illustrates a portable electronic device as the display device DD as an example, but embodiments according to the present disclosure are not limited thereto.

The display device DD may display an image IM at a display surface IS. The display surface IS may include a display region DA and a non-display region NDA adjacent to the display region DA. The non-display region NDA may be a region in which the image IM is not displayed. However, embodiments of the inventive concept are not limited thereto, and the non-display region NDA may be omitted. The display surface IS may include a plane defined by a first directional axis DR1 and a second directional axis DR2.

The display device DD according to some embodiments may be flexible. The wording “flexible” means bendable characteristics, and may include all structures from a structure completely bendable to a structure bendable to a several nanometer level. In addition, the display device DD may be rigid.

In the present disclosure, the first directional axis DR1 and the second directional axis DR2 may be orthogonal to each other and a third directional axis DR3 may be a direction normal to a plane defined by the first directional axis DR1 and the second directional axis DR2. A thickness direction of the display device DD may be parallel to the third directional axis DR3. With respect to the third directional axis DR3, the upper surface (or front surface, upper side) and the lower surface (or rear surface, lower side) facing the upper surface of each member constituting the display device DD may be defined. The upper surface (or front surface) may be more adjacent to the display surface IS than the lower surface (or rear surface).

Directions indicated by the first to third directional axes DR1, DR2, and DR3 described herein are relative concepts and may be changed to other directions. In addition, the directions indicated by the first to third directional axes DR1, DR2, and DR3 may be described as first to third directions, and the same reference numerals or symbols may be used.

Referring to FIG. 2, the display device DD may include a display module DM and a window WM located on the display module DM. In addition, the display device DD may further include a housing HAU accommodating or enclosing the display module DM.

In the display device DD illustrated in FIGS. 1 and 2, the window WM and the housing HAU may be coupled to form the exterior of the display device DD. The housing HAU may be located under the display module DM. The housing HAU may include a material having relatively high rigidity. For example, the housing HAU may include a plurality of frames and/or plates composed of glass, plastic, or metal. The housing HAU may provide an accommodation space (e.g., a set or predetermined accommodation space). The display module DM may be accommodated in the accommodation space and thus be protected from external impacts.

The display module DM may be activated in response to an electrical signal. The display module DM may be activated to display the image IM (see FIG. 1) on the display surface IS of the display device DD. An active region DM-AA and a peripheral region DM-NAA may be defined in the display module DM. The active region DM-AA may be activated in response to an electrical signal. The peripheral region DM-NAA may be positioned adjacent to at least one side of the active region DM-AA. A driving circuit, a driving line, or the like for driving the active region DM-AA may be located in the peripheral region DM-NAA.

The window WM may include a transmission region TA and a bezel region BZA. The transmission region TA may overlap at least a part of the active region DM-AA of the display module DM. The transmission region TA may be optically transparent. For example, the transmittance of the transmission region TA with respect to the visible wavelength range may be about 90% or more. The image IM may be provided to a user through the transmission region TA, and the user may receive information through the image IM.

The bezel region BZA may have a relatively lower transmittance than the transmission region TA. The bezel region BZA may define the shape of the transmission region TA. The bezel region BZA may be adjacent to the transmission region TA and may surround the transmission region TA.

The bezel region BZA may have a color (e.g., a set or predetermined color). The bezel region BZA may cover the peripheral region DM-NAA of the display module DM, and may thus block the peripheral region DM-NAA from being viewed from the outside. Meanwhile, this is an example, and the bezel region BZA may be omitted in the window WM according to some embodiments.

According to some embodiments, an adhesive member may be located between the display module DM and the window WM. The display module DM and the window WM may be coupled by the adhesive member. For example, the adhesive member may include a pressure sensitive adhesive (PSA) or an optically clear adhesive (OCA). However, embodiments according to the present disclosure are not limited thereto, and the adhesive member may include a typical adhesive.

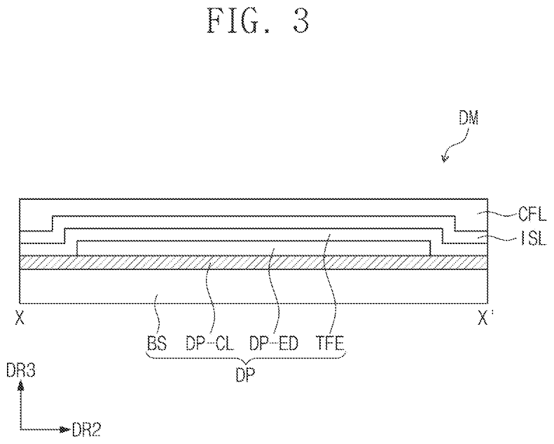

FIG. 3 is a cross-sectional view illustrating a part corresponding to the line X-X′ in FIG. 2, and is a cross-sectional view illustrating a display module DM in more detail. Referring to FIG. 3, the display module DM may include a display panel DP, an input sensing part ISL located on the display panel DP, and a color filter layer CFL located on the input sensing part ISL. The display module DM including the color filter layer CFL may not include a polarization plate. The display panel DP may include a base layer BS, a circuit layer DP-CL, a light-emitting element layer DP-ED, and an encapsulation layer TFE sequentially stacked.

The base layer BS may be a member that provides a base surface on which the circuit layer DP-CL is located. The base layer BS may be a rigid substrate, or a flexible substrate which is bendable, foldable, or rollable. The base layer BS may be a glass substrate, a metal substrate, a polymer substrate, or the like. However, embodiments of the inventive concept are not limited thereto, and the base layer BS may include an inorganic layer, an organic layer, or a composite material layer.

The base layer BS may have a multi-layered structure. For example, the base layer BS may have a three-layered structure of a synthetic resin layer, an adhesive layer, and a synthetic resin layer. In particular, the synthetic resin layer may include a polyimide-based resin. In addition, the synthetic resin layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. In the present disclosure, a “˜˜ based” resin means a resin including a “˜˜” functional group.

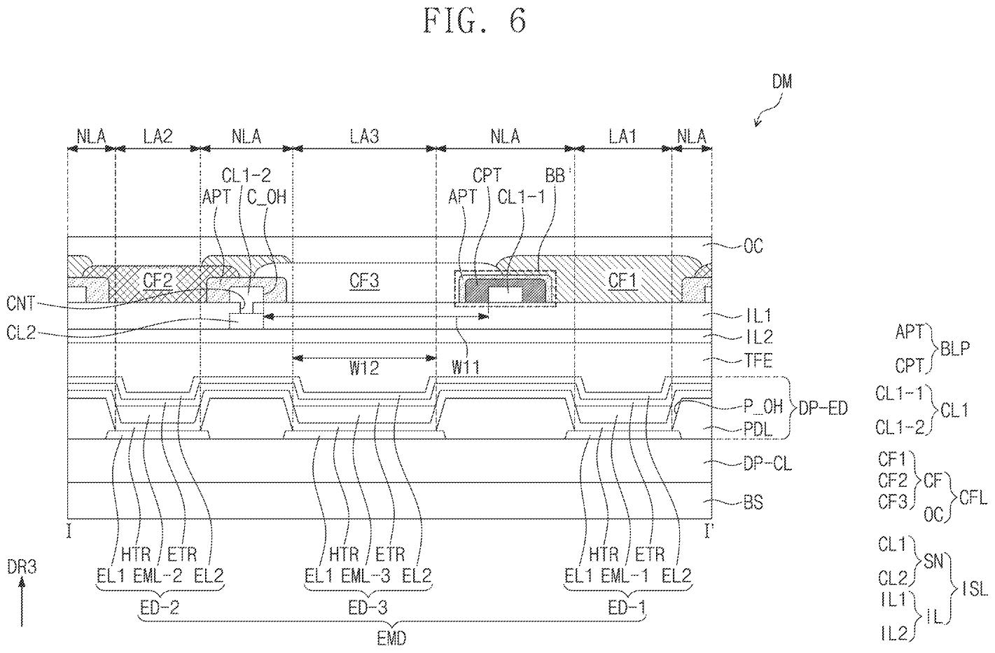

The circuit layer DP-CL may include an insulating layer, a transistor, etc. For example, the circuit layer DP-CL may include a switching transistor and a driving transistor for driving a light-emitting element EMD (see FIG. 6) of the light-emitting element layer DP-ED.

The light-emitting element layer DP-ED may include the light-emitting element EMD (see FIG. 6) to be described later. For example, the light-emitting element EMD (see FIG. 6) may include an organic light-emitting material, an inorganic light-emitting material, an organic-inorganic light-emitting material, quantum dots, quantum rods, a micro LED, or a nano LED.

The encapsulation layer TFE may include an organic material and/or an inorganic material. The encapsulation layer TFE may include at least one organic layer and at least one inorganic layer. For example, the encapsulation layer TFE may include a multi-layered structure in which a first inorganic layer, an organic layer, and a second inorganic layer are sequentially stacked. The first inorganic layer and the second inorganic layer of the encapsulation layer TFE may protect the light-emitting element EMD from external moisture and/or oxygen.

The first inorganic layer and the second inorganic layer may each include silicon nitride, silicon oxynitride, silicon oxide, titanium oxide, or aluminum oxide, and are not specially limited thereto. An organic layer of the encapsulation layer TFE may prevent or reduce denting of, or damage to, the light-emitting element EMD (see FIG. 6) due to foreign matters or contaminants introduced during a manufacturing process. The organic layer may include an acryl-based compound, an epoxy-based compound, or the like. The organic layer may include a photopolymerizable organic material, but is not specially limited thereto.

The input sensing part ISL may sense an external input to change the external input into an input signal (e.g., a set or predetermined input signal), and may provide the input signal to the display panel DP. For example, in the display device DD according to some embodiments, the input sensing part ISL may be a touch sensing part that senses a touch. The input sensing part ISL may recognize a direct touch of a user, an indirect touch of a user, a direct touch of an object, an indirect touch of an object, or the like.

The input sensing part ISL may sense at least one of the position or strength (pressure) of a touch applied from the outside. The input sensing part ISL may have various structures, or may be composed of various materials, and is not limited to any one embodiment. The input sensing part ISL may include a plurality of sensing electrodes SN (see FIG. 6) for sensing an external input. The sensing electrodes SN (see FIG. 6) may capacitively sense an external input. The display panel DP may receive an input signal from the input sensing part ISL, and may generate an image corresponding to the input signal.

The color filter layer CFL may include a color filter CF (see FIG. 6) to be described later. The color filter layer CFL may transmit and/or block light generated in the light-emitting element EMD (see FIG. 6).

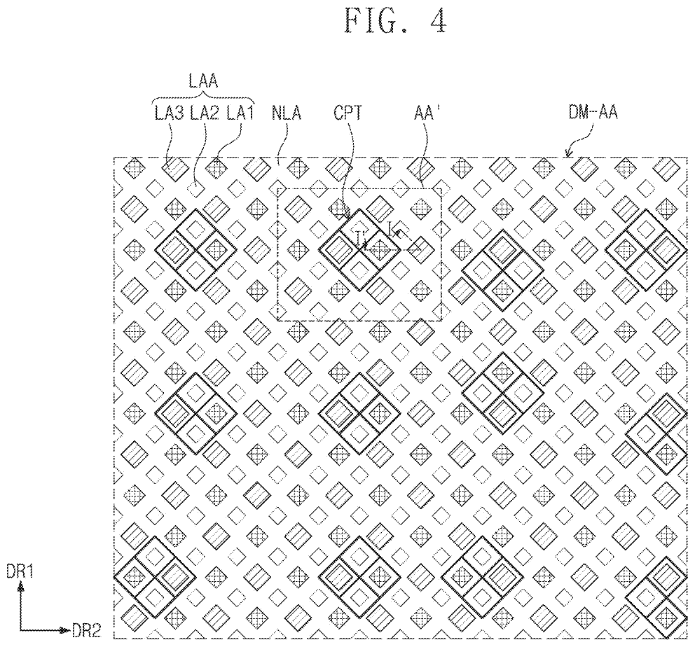

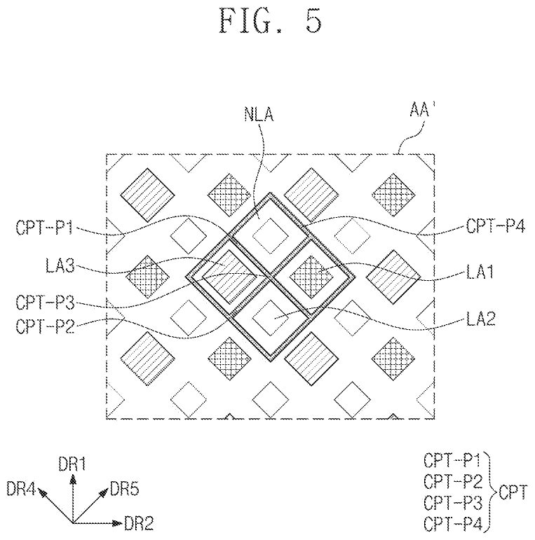

FIG. 4 is an enlarged plan view illustrating an active region DM-AA of a display module DM. FIG. 5 is an enlarged plan view of region AA′ in FIG. 4. On a plane defined by the first directional axis DR1 and the second directional axis DR2, the active region DM-AA may include a light-emitting region LAA and a non-light-emitting region NLA. The non-light-emitting region NLA may surround the light-emitting region LAA. In the active region DM-AA, a region other than the light-emitting region LAA may be defined as the non-light-emitting region NLA. The light-emitting region LAA may be defined to substantially correspond to a first electrode EL1 (see FIG. 6) exposed by a pixel opening P_OH to be described later.

The light-emitting region LAA may be provided in plurality. The light-emitting region LAA may include a first light-emitting region LA1, a second light-emitting region LA2, and a third light-emitting region LA3. The first light-emitting region LA1, the second light-emitting region LA2, and the third light-emitting region LA3 may respectively emit light having different wavelength ranges. The first light-emitting region LA1 may emit first color light, and the second light-emitting region LA2 may emit second color light different from the first color light. The third light-emitting region LA3 may emit third color light different from the first color light and the second color light. For example, the first color light may be red color light, the second color light may be green color light, and the third color light may be blue color light.

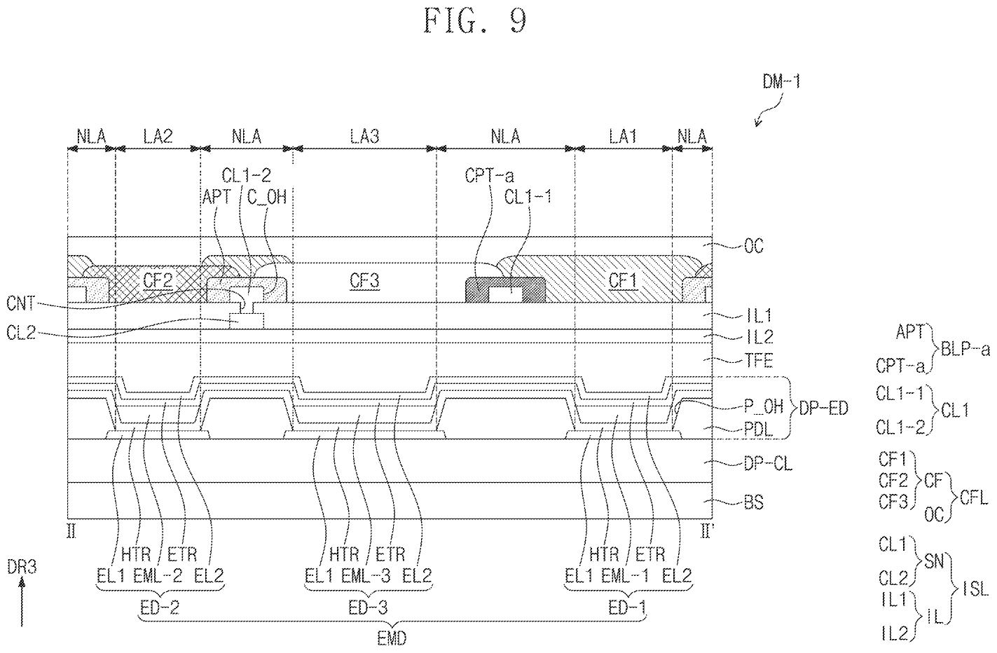

The display device DD according to some embodiments may include light-blocking patterns BLP, BLP-a, and BLP-b (see FIGS. 6, 9, and 12). The light-blocking patterns BLP, BLP-a, and BLP-b (see FIGS. 6, 9, and 12) may not overlap the light-emitting region LAA. The light-blocking patterns BLP, BLP-a, and BLP-b (see FIGS. 6, 9, and 12) may be located on a sensing electrode SN (see FIGS. 6, 9, and 12) of an input sensing part ISL to be described in more detail later. The light-blocking patterns BLP and BLP-a (see FIGS. 6 and 9) may include first pattern parts CPT and CPT-a and a second pattern part APT respectively including materials having different contents. Alternatively, a light-blocking pattern BLP-b may include a third pattern part PT-1 and a fourth pattern part PT-2 having different widths.

For convenience of description, the second pattern part APT (see FIG. 6) is omitted and the first pattern part CPT is illustrated in FIG. 4. According to some embodiments, the first pattern parts CPT and CPT-a and the second pattern part APT may have different optical densities (OD) with respect to first light. The first light may include light having a wavelength range of about 800 nm to about 1000 nm.

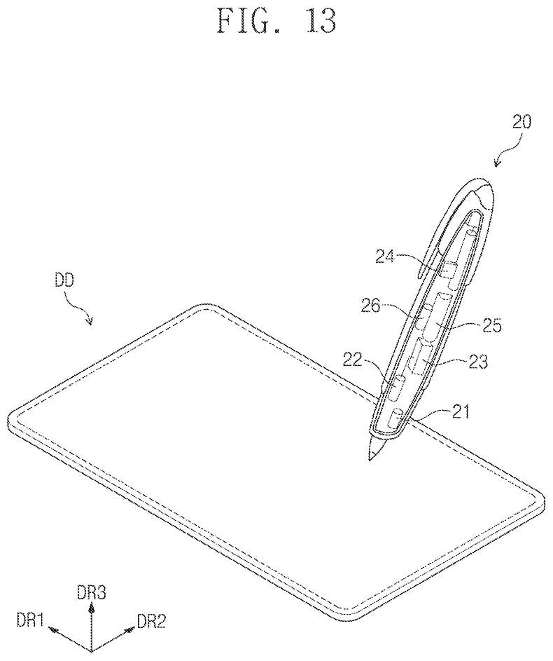

The first pattern part CPT may have an optical density of about 1 or more with respect to light having a wavelength range of about 800 nm to about 1000 nm. The first pattern part CPT having an optical density of about 1 or more with respect to light having a wavelength range of about 800 nm to about 1000 nm may perform a function of a code. The first pattern part CPT may absorb light having a wavelength range of about 800 nm to about 1000 nm to perform a function of a code. The first pattern part CPT may perform a function of a code including position information. The light having a wavelength range of about 800 nm to about 1000 nm may correspond to near-infrared light. Because the first pattern part CPT absorbs light having a wavelength range of about 800 nm to about 1000 nm, the first pattern part CPT may be recognized by a touch input unit 20 (see FIG. 13) to be described later.

On a plane defined by the first directional axis DR1 and the second directional axis DR2, the position information may be changed depending on the arrangement and shape of the first pattern part CPT. The first pattern part CPT may be provided in plurality. Referring to FIG. 4, it is illustrated that two most adjacent first pattern parts CPT are spaced apart from each other with one to three light-emitting regions LA therebetween. However, this is an example, and the spacing and the arrangement of the first pattern parts CPT are not limited to any one embodiment.

Referring to FIG. 5, the first pattern part CPT may include an intersection region CPT-P3, a first inner region CPT-P1, a second inner region CPT-P2, and an outer region CPT-P4. The first inner region CPT-P1 may extend from the intersection region CPT-P3 in a first extension direction DR4, and the second inner region CPT-P2 may extend from the intersection region CPT-P3 in a second extension direction DR5. On a plane defined by the first directional axis DR1 and the second directional axis DR2, the first extension direction DR4 and the second extension direction DR5 may cross each other.

On a plane defined by the first directional axis DR1 and the second directional axis DR2, the first extension direction DR4 and the second extension direction DR5 may be inclined right and left at an angle (e.g., a set or predetermined angle) with respect to the first directional axis DR1. The first extension direction DR4 may be inclined to the left side with respect to the first directional axis DR1, and the second extension direction DR5 may be inclined to the right side with respect to the first directional axis DR1. FIG. 5 illustrates that the first extension direction DR4 and the second extension direction DR5 are inclined with respect to the first directional axis DR1 at an angle of about 45°, but embodiments of the inventive concept are not limited thereto.

The first pattern part CPT may be arranged to surround one first light-emitting region LA1, two second light-emitting regions LA2, and one third light-emitting region LA3. The outer region CPT-P4 of the first pattern part CPT may have a closed square shape surrounding one first light-emitting region LA1, two second light-emitting regions LA2, and one third light-emitting region LA3. The outer region CPT-P4 of the first pattern part CPT may include two first sides extending in the first extension direction DR4 and two second sides extending in the second extension direction DR5. FIG. 4 illustrates that the length of the first side is substantially the same as the length of the second side, but embodiments of the inventive concept are not limited thereto.

In the outer region CPT-P4 having a closed square shape, the non-light-emitting region NLA may be located between adjacent light-emitting regions LAA. One first side and any one light-emitting region LAA included in the outer region CPT-P4 may be spaced apart from each other with the non-light-emitting region NLA therebetween. One second side and any one light-emitting region LAA included in the outer region CPT-P4 may be spaced apart from each other with the non-light-emitting region NLA therebetween.

The intersection region CPT-P3 of the first pattern part CPT may be provided inside the outer region CPT-P4 having a closed square shape. The intersection region CPT-P3 may be equidistantly spaced apart from each vertex of the outer region CPT-P4 having a square shape.

In the first pattern part CPT, the first inner region CPT-P1 and the second inner region CPT-P2 may be provided in the outer region CPT-P4. The first inner region CPT-P1 may be provided between two second sides of the outer region CPT-P4 extending in the second extension direction DR5. The second inner region CPT-P2 may be provided between two first sides extending in the first extension direction DR4.

The first inner region CPT-P1 may be provided between the third light-emitting region LA3 and one second light-emitting region LA2 spaced apart from a direction parallel to the second extension direction DR5, and between another second light-emitting region LA2 and the first light-emitting region LA1 spaced apart from a direction parallel to the second extension direction DR5. The second inner region CPT-P2 may be provided between the one second light-emitting region LA2 and the first light-emitting region LA1 spaced apart from a direction parallel to the first extension direction DR4, and between the third light-emitting region LA3 and another second light-emitting region LA2 spaced apart from a direction parallel to the first extension direction DR4. In the present disclosure, one second light-emitting region LA2 and another second light-emitting region LA2 may be located in different rows, and thus, on a plane, the one second light-emitting region LA2 may be located above the other second light-emitting region LA2.

FIG. 6 is a cross-sectional view illustrating a part corresponding to the line I-I′ in FIG. 4. Compared to FIG. 3, FIG. 6 illustrates a cross-sectional view of a display module DM in more detail.

Referring to FIG. 6, the display module DM may include a base layer BS, a circuit layer DP-CL located on the base layer BS, a light-emitting element layer DP-ED located on the circuit layer DP-CL, an encapsulation layer TFE located on the light-emitting element layer DP-ED, an input sensing part ISL located on the encapsulation layer TFE, and a color filter layer CFL located on the input sensing part ISL. The same content as described with reference to FIG. 3 may be applied to the base layer BS, the circuit layer DP-CL, and the encapsulation layer TFE in FIG. 6.

The light-emitting element layer DP-ED may include a light-emitting element EMD, and a pixel-defining film PDL. A pixel opening P_OH may be defined in the pixel-defining film PDL. The pixel-defining film PDL may include a black coloring agent. The black coloring agent may include a black dye and/or a black pigment. The black coloring agent may include carbon black, metal such as chromium, or an oxide thereof.

The light-emitting element EMD may include a first electrode EL1, a second electrode EL2 located on the first electrode EL1, and light-emitting layers EML-1, EML-2, and EML-3 located between the first electrode EL1 and the second electrode EL2. The light-emitting element EMD may be provided in plurality. The light-emitting element EMD may include a first light-emitting element ED-1 that emits first color light, a second light-emitting element ED-2 that emits second color light, and a third light-emitting element ED-3 that emits third color light. The first light-emitting element ED-1 may emit red color light, the second light-emitting element ED-2 may emit green color light, and the third light-emitting element ED-3 may emit blue color light. The first light-emitting region LA1 may correspond to the first light-emitting element ED-1, the second light-emitting region LA2 may correspond to the second light-emitting element ED-2, and the third light-emitting region LA3 may correspond to the third light-emitting element ED-3.

The first to third light-emitting elements ED-1, ED-2, and ED-3 may respectively include the first electrode EL1, the second electrode EL2, and the light-emitting layers EML-1, EML-2, and EML-3. A part of the first electrode EL1 may be covered by the pixel-defining film PDL. A part of the first electrode EL1 may be exposed by the pixel opening P_OH. The light-emitting region LAA may be defined corresponding to the part of the first electrode EL1 exposed by the pixel opening P_OH.

The first electrode EL1 may be a transparent electrode, a transflective electrode, or a reflective electrode. When the first electrode EL1 is a transparent electrode, the first electrode EL1 may include a transparent metal oxide, for example, indium-tin oxide (ITO), indium-zinc oxide (IZO), zinc oxide (ZnO), indium-tin-zinc oxide (ITZO), or the like. When the first electrode EL1 is a transflective electrode, or a reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/AI (a stack structure of LiF and Al), Mo, Ti, W, or a compound or mixture thereof (for example, a mixture of Ag and Mg).

The first light-emitting element ED-1 may include a first light-emitting layer EML-1 located between the first electrode EL1 and the second electrode EL2. The first light-emitting layer EML-1 may emit the first color light. The second light-emitting element ED-2 may include the second light-emitting layer EML-2 located between the first electrode EL1 and the second electrode EL2. The second light-emitting layer EML-2 may emit the second color light. The third light-emitting element ED-3 may include the third light-emitting layer EML-3 located between the first electrode EL1 and the second electrode EL2. The third light-emitting layer EML-3 may emit the third color light.

The first to third light-emitting layers EML-1, EML-2, and EML-3 may be located in the pixel opening P_OH, and may respectively correspond to first to third light-emitting regions LA1, LA2, and LA3. The light-emitting layers EML-1, EML-2, and EML-3 may each include an organic light-emitting material, an inorganic light-emitting material, an organic-inorganic light-emitting material, quantum dots, quantum rods, a micro LED, or a nano LED.

Referring to FIG. 6, the second electrode EL2 may have an integrated shape, and may be provided as a common later. Unlike what is illustrated, the second electrode EL2 may be provided to be separated by the pixel-defining film PDL in correspondence to the first to third light-emitting elements ED-1, ED-2, and ED-3.

The second electrode EL2 may be a transparent electrode, a transflective electrode, or a reflective electrode. When the second electrode EL2 is a transparent electrode, the second electrode EL2 may include a transparent metal oxide, for example, indium-tin oxide (ITO), indium-zinc oxide (IZO), zinc oxide (ZnO), indium-tin-zinc oxide (ITZO), or the like.

When the second electrode EL2 is a transflective electrode, or a reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, or a compound or mixture including the same (for example, AgMg, AgYb, or MgYb). Alternatively, the second electrode EL2 may have a multi-layered structure including a reflective film or a transflective film composed of the above material, and a transparent conductive film composed of indium-tin oxide (ITO), indium-zinc oxide (IZO), zinc oxide (ZnO), indium-tin-zinc oxide (ITZO), or the like.

In addition, the first to third light-emitting elements ED-1, ED-2, and ED-3 may each include a hole transport region HTR located between the first electrode EL1 and the light-emitting layers EML-1, EML-2, and EML-3, and an electron transport region ETR located between the second electrode EL2 and the light-emitting layers EML-1, EML-2, and EML-3. The hole transport region HTR and the electron transport region ETR may be provided as common layers. The hole transport region HTR may include at least one of a hole injection layer, a hole transport layer, or an electron-blocking layer. The electron transport region ETR may include at least one of an electron injection layer, an electron transport layer, or a hole-blocking layer.

The input sensing part ISL may include a sensing electrode SN, and an insulating layer IL. The insulating layer IL may include a base insulating layer IL2 located on the encapsulation layer TFE, and an input insulating layer IL1 located on the base insulating layer IL2. The base insulating layer IL2 may include a single layer or a multi-layer. The base insulating layer IL2 may be an inorganic layer including at least one of silicon nitride, silicon oxynitride, or silicon oxide. Alternatively, the base insulating layer IL2 may be an organic layer including an epoxy-based resin, an acryl-based resin, or an imide-based resin.

The input insulating layer IL1 may include an inorganic film. The inorganic film may include at least one of aluminum oxide, titanium oxide, silicon oxide, silicon nitride, silicon oxynitride, zirconium oxide, or hafnium oxide. Alternatively, the input insulating layer IL1 may include an organic film. The organic film may include at least one of an epoxy-based resin, a urethane-based resin, a cellulose-based resin, a siloxane-based resin, a polyimide-based resin, a polyamide-based resin, or a perylene-based resin.

The sensing electrode SN may be located on the pixel-defining film PDL, and may overlap the pixel-defining film PDL. In the present disclosure, the phrase, “one component overlaps another component” is not limited to “the one component has the same area and shape as the other component on a plane”, and includes “the one component has a different area and/or shape from the other component”. The plane means a plane perpendicular to the thickness direction DR3.

The sensing electrode SN may include a first conductive line CL1 that defines an electrode opening C_OH. The first conductive line CL1 may be located on the input insulating layer IL1. In addition, the sensing electrode SN may include a second conductive line CL2 located on the base insulating layer IL2. The second conductive line CL2 may be electrically connected to the first conductive line CL1 via a contact hole CNT passing through the input insulating layer IL1. The second conductive line CL2 may be covered by the input insulating layer IL1. An electrode opening may not be defined in the second conductive line CL2. Alternatively, the electrode opening may be defined in the second conductive line CL2.

The first conductive line CL1 and the second conductive line CL2 may each include a single layer or a multi-layer. The first conductive line CL1 and the second conductive line CL2 may each include a metal layer or a transparent conductive layer as a single layer. The metal layer may include molybdenum (Mo), silver (Ag), titanium (Ti), copper (Cu), aluminum (Al), or an alloy thereof. The transparent conductive layer may include a transparent conductive oxide such as indium-tin oxide (ITO), indium-zinc oxide (IZO), and indium-tin-zinc oxide (ITZO). In addition, the transparent conductive layer may include a conductive polymer such as PEDOT, metal nanowire, graphene, or the like. For example, the first conductive line CL1 and the second conductive line CL2 may each have a three-layered structure of ITO/Ag/ITO. In addition, the first conductive line CL1 and the second conductive line CL2 may each include at least one metal layer and at least one transparent conductive layer.

The first conductive line CL1 and the second conductive line CL2 may overlap the pixel-defining film PDL. The first conductive line CL1 and the second conductive line CL2 may be located in the non-light-emitting region NLA.

In the first conductive line CL1, the electrode opening C_OH may be defined by a first part CL1-1 and a second part CL1-2. FIG. 6 illustrates that the second part CL1-2 of the first conductive line CL1 is electrically connected to the second conductive line CL2 through the contact hole CNT, but embodiments of the inventive concept are not limited thereto.

The electrode opening C_OH may be defined to correspond to the light-emitting element EMD. More specifically, a plurality of electrode openings C_OH may be defined to respectively correspond to the first light-emitting element ED-1, the second light-emitting element ED-2, and the third light-emitting element ED-3.

In a direction perpendicular to the thickness direction DR3, the pixel-defining film PDL may have a greater width than the first conductive line CL1 and the second conductive line CL2. Accordingly, in the direction perpendicular to the thickness direction DR3, a width W11 of the electrode opening C_OH may be greater than a width W12 of the pixel opening P_OH. In the direction perpendicular to the thickness direction DR3, the width W12 of the pixel opening P_OH may be the minimum width of the pixel opening P_OH adjacent to the first electrode EL1. In a direction perpendicular to the thickness direction DR3, the width W12 of the pixel opening P_OH may be substantially the same as a width of the light-emitting region LAA. However, this is an example, and the width W12 of the pixel opening P_OH is not limited thereto.

A light-blocking pattern BLP may be located on the sensing electrode SN. The light-blocking pattern BLP may overlap the sensing electrode SN. The light-blocking pattern BLP may include a first pattern part CPT and a second pattern part APT which have different optical densities with respect to light having a wavelength range of about 800 nm to about 1000 nm. The first pattern part CPT and the second pattern part APT may be located on the first conductive line CL1.

The light-blocking pattern BLP may not overlap the light-emitting region LAA. The light-blocking pattern BLP may not overlap the pixel opening P_OH. The light-blocking pattern BLP may be provided in the non-light-emitting region NLA.

The first pattern part CPT may have an optical density of about 1 or more with respect to light having a wavelength range of about 800 nm to about 1000 nm. For example, the first pattern part CPT may have an optical density of about 2 with respect to light having a wavelength range of about 800 nm to about 1000 nm.

The first pattern part CPT having an optical density of about 1 or more may have a low light transmittance and a high light absorbance. That is, the first pattern part CPT having an optical density of about 1 or more with respect to light having a wavelength range of about 800 nm to about 1000 nm may have a high absorbance with respect to light having a wavelength range of about 800 nm to about 1000 nm. The first pattern part CPT having a high absorbance with respect to light having a wavelength range of about 800 nm to about 1000 nm may perform a function of a code including position information.

The second pattern part APT may have an optical density of less than 1 with respect to light having a wavelength range of about 800 nm to about 1000 nm. The second pattern part APT having an optical density of less than 1 with respect to light having a wavelength range of about 800 nm to about 1000 nm may have a high transmittance with respect to light having a wavelength range of about 800 nm to about 1000 nm. For example, the second pattern part APT may have a transmittance of about 10% or more with respect to light having a wavelength range of about 800 nm to about 1000 nm. The second pattern part APT having a high transmittance with respect to light having a wavelength range of about 800 nm to about 1000 nm may not include position information. The second pattern part APT may be provided to cover the sensing electrode SN. More specifically, the second pattern part APT may cover at least a part of the first conductive line CL1.

According to some embodiments, the light-blocking pattern BLP may include the first pattern part CPT and the second pattern part APT which are located on the same layer (for example, the sensing electrode SN). The first pattern part CPT and the second pattern part APT may have different optical densities with respect to light having a wavelength range of about 800 nm to about 1000 nm. Because the first pattern part CPT and the second pattern part APT have different optical densities with respect to light having a wavelength range of about 800 nm to about 1000 nm, the first pattern part CPT having a relatively great optical density may perform a function of a code including position information by a touch input unit 20 (see FIG. 13) to be described later. In addition, the second pattern part APT having a relatively small optical density may not perform a function of a code including position information.

The first pattern part CPT and the second pattern part APT may each include an infrared reactive material that absorbs light having a wavelength range of about 800 nm to about 1000 nm. With respect to the total weight of the first pattern part CPT, the infrared reactive material may be provided in a first content. With respect to the total weight of the second pattern part APT, the infrared reactive material may be provided in a second content smaller than the first content. For example, the first content may be at least five times of the second content. More specifically, the first content may be about 60 wt %, and the second content may be more than 0 wt % and about 1 wt % or less. However, this is an example, and the values of the first content and the second content are not limited thereto.

The first pattern part CPT having a relatively great content of the infrared reactive material may have a great optical density with respect to light having a wavelength range of about 800 nm to about 1000 nm. The first pattern part CPT having a relatively great content of the infrared reactive material may have a high absorbance with respect to light having a wavelength range of about 800 nm to about 1000 nm. In addition, the second pattern part APT having a relatively small content of the infrared reactive material may have a small optical density with respect to light having a wavelength range of about 800 nm to about 1000 nm. The second pattern part APT having a relatively small content of the infrared reactive material may have a high transmittance with respect to light having a wavelength range of about 800 nm to about 1000 nm

In the first pattern part CPT and the second pattern part APT, the infrared reactive material may include an organic material or an inorganic material. When the first pattern part CPT and the second pattern part APT include an organic material, the organic material may be reactive in response to light or heat. Alternatively, when the first pattern part CPT and the second pattern part APT include an inorganic material, the inorganic material may be a silicon-based inorganic material. For example, the infrared reactive material may include carbon. The carbon may absorb light having a wavelength range of about 800 nm to about 1000 nm. In addition, the infrared reactive material may further include silicon. For example, the infrared reactive material may include silicon carbide.

On a cross-section parallel to the thickness direction DR3, the first pattern part CPT and the second pattern part APT may be spaced apart from each other. In FIG. 6, the second pattern part APT may be located in the first part CL1-1 of the first conductive line CL1, and the second pattern part APT may be located in the second part CL1-2 of the first conductive line CL1.

Alternatively, the second pattern part APT may be located on the first pattern part CPT. Referring to FIG. 6, the first pattern part CPT may be located in the first part CL1-1 of the first conductive line CL1, and the second pattern part APT may be located on the first pattern part CPT. When the second pattern part APT is located on the first pattern part CPT, the second pattern part APT has a relatively low optical density, and the first pattern part CPT has a relatively high optical density, so that light having a wavelength range of about 800 nm to about 1000 nm may penetrate the second pattern part APT. The penetrating light may be absorbed by the first pattern part CPT.

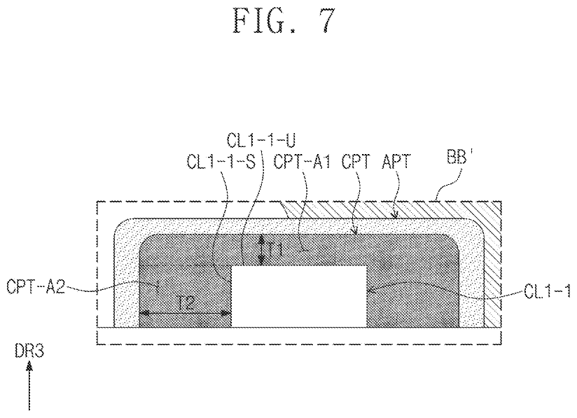

FIG. 7 is an enlarged cross-sectional view of region BB′ in FIG. 6. Referring to FIG. 7, a first pattern part CPT may be in contact with a first part CL1-1 of a first conductive line CL1. More specifically, the first pattern part CPT may be in contact with an upper surface CL1-1-U of the first part CL1-1 and a side surface CL1-1-S of the first part CL1-1. The first pattern part CPT may include a first region CPT-A1 in contact with the upper surface CL1-1-U of the first part CL1-1 and a second region CPT-A2 in contact with the side surface CL1-1-S of the first part CL1-1. A first length T1 of the first region CPT-A1 may be shorter than a second length T2 of the second region CPT-A2. The first length T1 may be a length in the normal direction to the upper surface CL1-1-U of the first part CL1-1, and the second length T2 may be a length in the normal direction to the side surface CL1-1-S of the first part CL1-1. The first pattern part CPT formed on the side surface of the first part CL1-1 may be thicker than that formed on the upper surface of the first part CL1-1.

Referring FIG. 6 again, a color filter layer CFL may be located on the sensing electrode SN. The color filter layer CFL may include a color filter CF, and the color filter CF may overlap the sensing electrode SN. The color filter CF may include first to third filters CF1, CF2 and CF3.

The first filter CF1 may emit first color light emitted from the first light-emitting element ED-1. The second filter CF2 may emit second color light emitted from the second light-emitting element ED-2. The third filter CF3 may emit third color light emitted from the third light-emitting element ED-3. The first filter CF1 may block the second color light and the third color light. The second filter CF2 may block the first color light and the third color light. The third filter CF3 may block the first color light and the second color light.

For example, the first filter CF1 may be a red color filter, the second filter CF2 may be a green color filter, and the third filter CF3 may be a blue color filter. The first to third filters CF1, CF2 and CF3 may each include a polymer photosensitive resin and a pigment or dye. The first filter CF1 may include a red pigment or dye, the second filter CF2 may include a green pigment or dye, and the third filter CF3 may include a blue pigment or dye. However, embodiments of the inventive concept are not limited thereto, and the third filter CF3 may not include a pigment or dye. The third filter CF3 may include a polymer photosensitive resin, and may not include a pigment or dye. The third filter CF3 may be transparent. The third filter CF3 may be formed of a transparent photosensitive resin.

The first to third filters CF1, CF2 and CF3 may be each include filling electrode openings C_OH defined in the first conductive line CL1. At least two filters among the first to third filters CF1, CF2 and CF3 may overlap each other on a light-blocking pattern BLP. Referring to FIG. 6, the first filter CF1 and the third filter CF3 may overlap each other on the first pattern part CPT. The first filter CF1 and the second filter CF2 may overlap each other on the second pattern part APT. In addition, the first to third filters CF1, CF2 and CF3 may overlap each other on the second pattern part APT.

The first to third filters CF1, CF2 and CF3 may prevent or reduce visibility of the first pattern part CPT. When the display device DD according to some embodiments is manufactured, the first pattern part CPT may be formed on the first conductive line CL1, and the second pattern part APT may be formed on the first pattern part CPT and the first conductive line CL1 on which the first pattern part CPT is not formed. Then, the color filters CF may be formed on the first pattern part CPT and the second pattern part APT.

Because a first pattern part is provided on color filters in a typical display device, the first pattern part is visible from the outside of the display device. In the display device DD according to some embodiments, because the color filters CF are located on the first pattern part CPT, the first pattern part CPT may not be viewed from the outside of the display device DD. Accordingly, the display device DD according to some embodiments may exhibit excellent reliability.

The color filter layer CFL may further include an overcoat layer OC. The overcoat layer OC may be located on the first to third filters CF1, CF2 and CF3. The overcoat layer OC may be a planarization layer. The overcoat layer OC may be optically transparent. For example, the overcoat layer OC may include an optically transparent organic material.

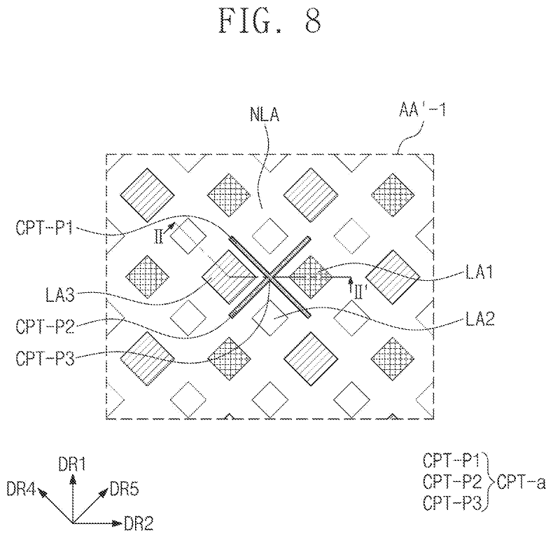

FIGS. 8 to 12 illustrate other embodiments of the inventive concept. Hereinafter, in description of FIGS. 8 to 12, content duplicated with those described above with reference to FIGS. 1A to 7 will not be described again, and differences will be mainly described.

FIG. 8 illustrates region AA′-1 which is another example of region AA′. For convenience of description, the second pattern part APT is omitted in FIG. 8. In FIG. 8, on a plane defined by the first directional axis DR1 and the second directional axis DR2, the shape of a first pattern part CPT-a is different from the shape of the first pattern part CPT in FIG. 5. FIG. 9 is a cross-sectional view illustrating a part corresponding to the line II-II′ in FIG. 8, and illustrates a display module DM-1 including a light-blocking pattern BLP-a different from the light-blocking pattern BLP described with reference to FIG. 6.

The first pattern part CPT-a in FIG. 8 may be formed as an open-type pattern, unlike the first pattern part CPT in FIG. 5. The first pattern part CPT-a in FIG. 8 may not include the outer region CPT-P4 (see FIG. 5). The first pattern part CPT-a in FIG. 8 may include an intersection region CPT-P3, a first inner region CPT-P1 extending in the first extension direction DR4 from the intersection region CPT-P3, and a second inner region CPT-P2 extending in the second extension direction DR5 from the intersection region CPT-P3. For example, the first pattern part CPT in FIG. 5 and the first pattern part CPT-a in FIG. 8 may include different position information.

Referring to FIG. 9, the light-blocking pattern BLP-a may include the first pattern part CPT-a located on a first part CL1-1 of a first conductive line CL1 and the second pattern part APT located on a second part CL1-2 of the first conductive line CL1. Compared to the display module DM in FIG. 6, a display module DM-1 in FIG. 9 has a difference in that the second pattern part APT (see FIG. 6) is not located on the first part CL1-1 of the first conductive line CL1.

The first pattern part CPT-a located on the first conductive line CL1 may have an optical density of about 1 or more with respect to light having a wavelength range of about 800 nm to about 1000 nm. The first pattern part CPT-a may have a high absorbance with respect to light having a wavelength range of about 800 nm to about 1000 nm. The second pattern part APT may have an optical density of less than about 1 with respect to light having a wavelength range of about 800 nm to about 1000 nm. The first pattern part CPT-a may have a high transmittance with respect to light having a wavelength range of about 800 nm to about 1000 nm. Accordingly, the first pattern part CPT-a may perform a function of a code including position information. According to some embodiments, because the first pattern part CPT-a is located on a sensing electrode SN, and color filters CF are located on the first pattern part CPT-a, the first pattern part CPT-a may be prevented from being viewed.

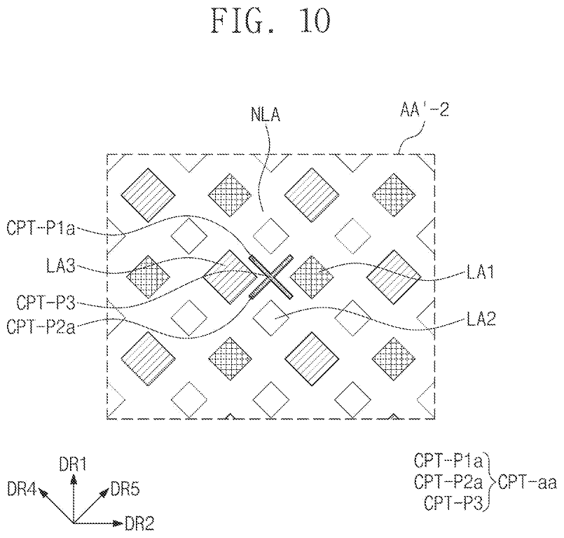

FIG. 10 illustrates region AA′-2 which is another example of region AA′. On a plane defined by the first directional axis DR1 and the second directional axis DR2, FIG. 10 illustrates a first pattern part CPT-aa of which the shape is different from the shape of the first pattern part CPT in FIG. 5 and the shape of the first pattern part CPT-a in FIG. 8.

Compared to the first pattern part CPT-a in FIG. 8, the first pattern part CPT-aa in FIG. 10 has a difference in that a length of the first inner region CPT-P1a and a length of the second inner region CPT-P2a are shorter. The length of the first inner region CPT-P1a may be parallel to the first extension direction DR4, and the length of the second inner region CPT-P2a may be parallel to the second extension direction DR5. The first pattern part CPT-aa in FIG. 10 may be formed as an open-type pattern. The first pattern part CPT-aa in FIG. 10 may not include the outer region CPT-P4 (see FIG. 5).

Between a third light-emitting region LA3 and one second light-emitting region LA2 and between another second light-emitting region LA2 and a first light-emitting region LA1, the length of the first inner region CPT-P1a may be shorter than the length of the first inner region CPT-P1 illustrated in FIG. 8. Between the third light-emitting region LA3 and the other second light-emitting region LA2 and between the one second light-emitting region LA2 and the first light-emitting region LA1, the length of the second inner region CPT-P2a may be shorter than the length of the second inner region CPT-P2 illustrated in FIG. 8.

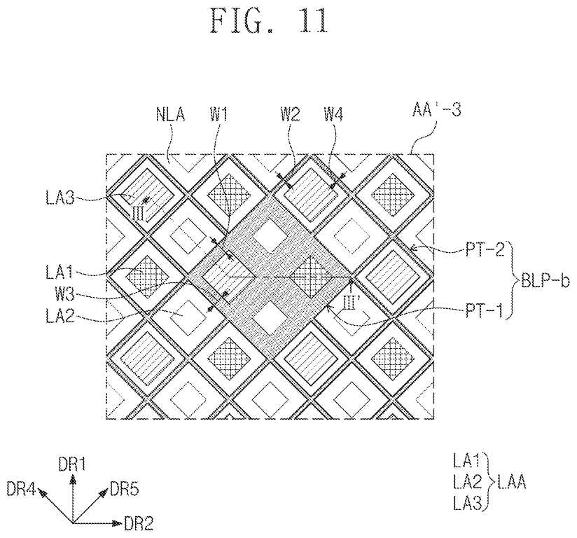

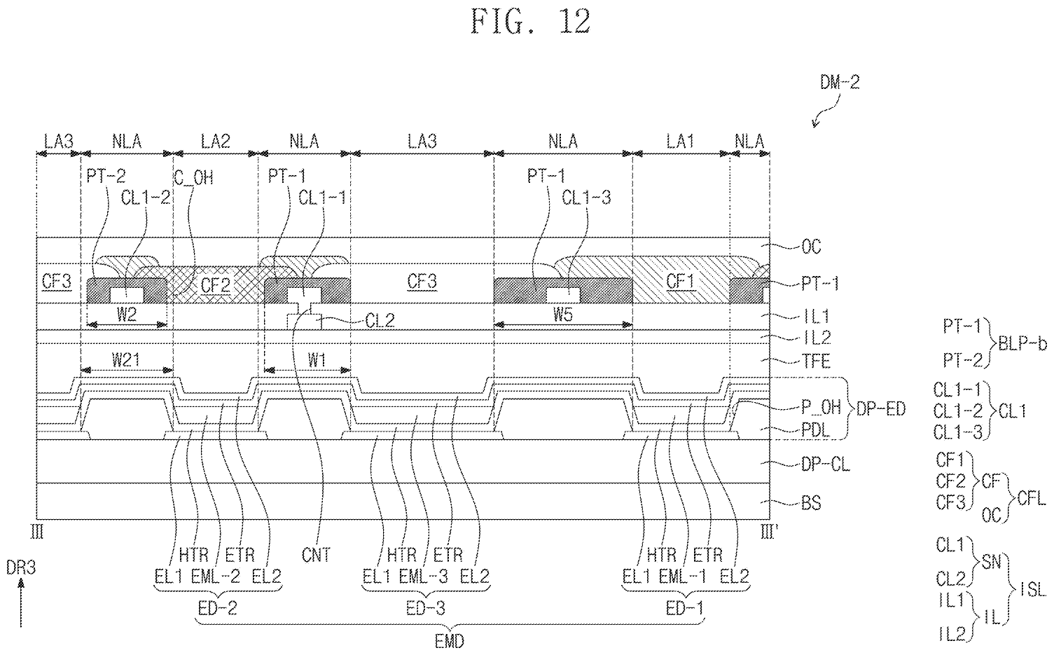

FIG. 11 illustrates AA′-3 which is another example of region AA′, and FIG. 12 is a cross-sectional view illustrating a part corresponding to the line III-Ill′ in FIG. 11. FIG. 12 illustrates a display module DM-2 including a light-blocking pattern BLP-b different from the light-blocking pattern BLP described with reference to FIG. 6.

According to some embodiments, the light-blocking pattern BLP-b may include a third pattern part PT-1 and a fourth pattern part PT-2. The third pattern part PT-1 and the fourth pattern part PT-2 may each have an optical density (OD) of about 1 or more with respect to light having a wavelength range of about 800 nm to about 1000 nm. The third pattern part PT-1 and the fourth pattern part PT-2 may have different widths. The third pattern part PT-1 may have a first width W1, and the fourth pattern part PT-2 may have a second width W2 smaller than the first width W1. The third pattern part PT-1 having a relatively great first width W1 may perform a function of a code including position information. The fourth pattern part PT-2 having a relatively small second width W2 may not perform a function of a code including position information.

On a plane defined by the first directional axis DR1 and the second directional axis DR2, the third pattern part PT-1 and the fourth pattern part PT-2 may each extend in the first extension direction DR4 and in the second extension direction DR5. The first width W1 of the third pattern part PT-1 may be parallel to the first extension direction DR4 or the second extension direction DR5. The second width W2 of the fourth pattern part PT-2 may be parallel to the first extension direction DR4 or the second extension direction DR5.

For example, the first width W1 of the third pattern part PT-1 and the second width W2 of the fourth pattern part PT-2 may be parallel to the first extension direction DR4. The third pattern part PT-1 may be located adjacent to the light-emitting region LAA. More specifically, the third pattern part PT-1 may be adjacent to a borderline that demarcates at least one light-emitting region LAA. The fourth pattern part PT-2 may be formed to be spaced apart from the light-emitting region LAA by a distance (e.g., a set or predetermined distance). Accordingly, the first width W1 may be relatively thicker than the second width W2. The third pattern part PT-1 having a relatively great first width W1 may perform a function of a code including position information.

In addition, the third pattern part PT-1 may have a third width W3 parallel to the second extension direction DR5, and the fourth pattern part PT-2 may have a fourth width W4 parallel to the second extension direction DR5. The fourth width W4 may be smaller than the third width W3. The fourth width W4 may be substantially the same as the second width W2. The fourth pattern part PT-2 may be formed to substantially have the same width in the first extension direction DR4 and the second extension direction DR5. Alternatively, the fourth pattern part PT-2 may be formed to have different widths in the first extension direction DR4 and the second extension direction DR5.

The third width W3 may be substantially the same as the first width W1. The third width W3 and the first width W1 may respectively be a width of one region and a width of another region of the third pattern part PT-1 adjacent to the same light-emitting region LAA. For example, the other region adjacent to the third light-emitting region LA3 and parallel to the first extension direction DR4 in third pattern part PT-1 may have the first width W1. The one region adjacent to the third light-emitting region LA3 and parallel to the second extension direction DR5 in third pattern part PT-1 may have the third width W3. The first width W1 and the third width W3 adjacent to the same light-emitting region LAA in the third pattern part PT-1 may be substantially the same. However, embodiments of the inventive concept are not limited thereto, and the first width W1 and the third width W3 may be different.

Referring to FIG. 11, the third pattern part PT-1 may extend in the first extension direction DR4 and the second extension direction DR5, and may be formed as a closed-type pattern. The closed third pattern part PT-1 may be arranged to fill the non-light-emitting region NLA between the light-emitting regions LAA. For example, the third pattern part PT-1 may have a closed square shape surrounding at least one light-emitting region LAA, and may be arranged to fill the non-light-emitting region NLA in the square shape. FIG. 11 illustrates that the third pattern part PT-1 is formed as a closed square shape surrounding one first light-emitting region LA1, two second light-emitting region LA2, and one third light-emitting region LA3. Accordingly, the third pattern part PT-1 may overlap the non-light-emitting region NLA between the one first light-emitting region LA1, the two second light-emitting region LA2, and the one third light-emitting region LA3. The third pattern part PT-1 may be arranged to fill the non-light-emitting region NLA between the one first light-emitting region LA1, the two second light-emitting region LA2, and the one third light-emitting region LA3. However, this is an example, and the number and type of the light-emitting regions LAA surrounded by the closed third pattern part PT-1 are not limited thereto. In addition, the third pattern part PT-1 may be formed as an open-type pattern.

The fourth pattern part PT-2 may extend from an edge of the third pattern part PT-1. Referring to FIG. 11, the fourth pattern part PT-2 may extend from one side edge of the third pattern part PT-1 parallel to the first extension direction DR4 in the second extension direction DR5. The fourth pattern part PT-2 may extend from the other side edge of the third pattern part PT-1 parallel to the second extension direction DR5 in the first extension direction DR4.

The third pattern part PT-1 and the fourth pattern part PT-2 may each include an infrared reactive material that absorbs light having a wavelength range of about 800 nm to about 1000 nm. For example, the infrared reactive material may include carbon. In addition, the infrared reactive material may further include silicon. The third pattern part PT-1 and the fourth pattern part PT-2 may include the infrared reactive materials of which the contents are substantially equal to each other. Because the first width W1 of the third pattern part PT-1 is greater than the second width W2 of the fourth pattern part PT-2, the third pattern part PT-1 may perform a function of a code including position information. The display device DD in which the third pattern part PT-1 and the fourth pattern part PT-2 include the infrared reactive materials in the same amount may be improved in terms of manufacturing costs and manufacturing efficiency.

Referring to FIG. 12, the first conductive line CL1 in which electrode openings C_OH are defined may include a first part CL1-1 and a second part CL1-2. In addition, the first conductive line CL1 in which the electrode openings C_OH are defined may further include a third part CL1-3. On a cross-section parallel to the thickness direction DR3, the first part CL1-1, the second part CL1-2, and the third part CL1-3 may be spaced apart from each other in a direction perpendicular to the thickness direction DR3. According to some embodiments, the third pattern part PT-1 may overlap the first part CL1-1 of the first conductive line CL1, and the fourth pattern part PT-2 may overlap the second part CL1-2 of the first conductive line CL1. For example, the third pattern part PT-1 may be in contact with the first part CL1-1, and the fourth pattern part PT-2 may be in contact with the second part CL1-2. On a cross-section parallel to the third direction DR3, the third pattern part PT-1 and the fourth pattern part PT-2 may be spaced apart from each other. The third pattern part PT-1 and the fourth pattern part PT-2 may be spaced apart in a direction perpendicular to the thickness direction DR3.

A first width W1 of the third pattern part PT-1 and a second width W2 of the fourth pattern part PT-2 may be smaller than a width W21 of the pixel-defining film PDL. The width W21 of the pixel-defining film PDL may be a width in a region adjacent to an upper surface of the circuit layer DP-CL, and may be the maximum width in the pixel-defining film PDL. The upper surface of the circuit layer DP-CL may be adjacent to the light-emitting element layer DP-ED, and the lower surface of the circuit layer DP-CL may be adjacent to the base layer BS.

In addition, the third pattern part PT-1 may overlap the third part CL1-3. The third pattern part PT-1 overlapping the third part CL1-3 may have a fifth width W5. The fifth width W5 may be greater than the first width W1 and the second width W2. The fifth width W5 may be substantially the same as the width W21 of the pixel-defining film PDL.

Referring to FIG. 12, the color filters CF may be located on the light-blocking pattern BLP-b. According to some embodiments, the color filters CF may be located on the third pattern part PT-1 and the fourth pattern part PT-2. Accordingly, the display device DD according to some embodiments including the color filters CF located on the third pattern part PT-1 and the fourth pattern part PT-2 may prevent or reduce instances of the third pattern part PT-1 and the fourth pattern part PT-2 being viewed from the outside.

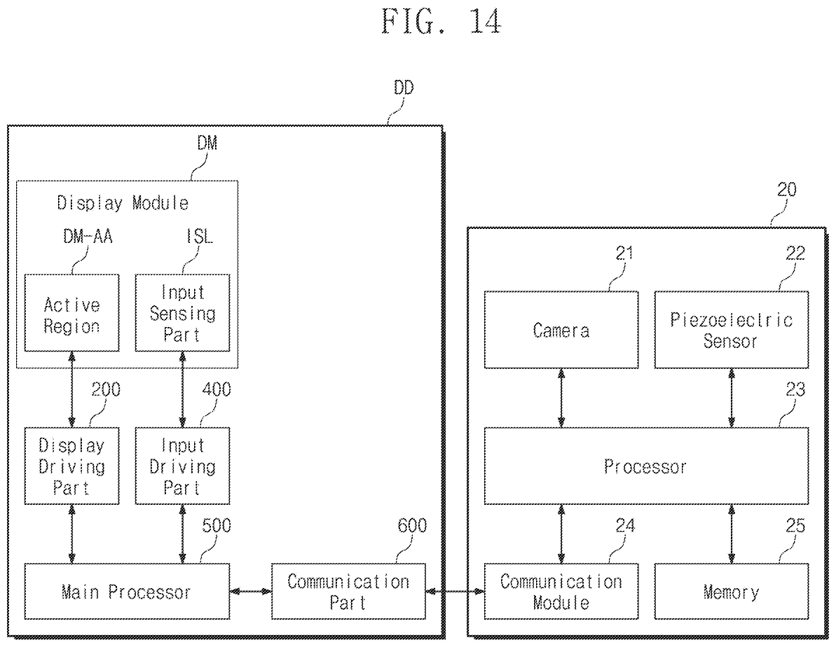

FIG. 13 is a perspective view illustrating a display device DD and a touch input device 20 according to some embodiments. FIG. 14 is a block diagram illustrating the display device DD and the touch input device 20.

The display device DD may include a display driving part 200, an input driving part 400, a main processor 500, and a communication part 600. The display driving part 200 may be located in a peripheral region DM-NAA (see FIG. 2), and may output signals and voltages for driving a display panel DP (see FIG. 3). The display driving part 200 may be configured with an integrated circuit (IC), and may be mounted on the display panel DP through a chip-on glass (COG) method, a chip-on-plastic (COP) method, or an ultrasonic bonding method.

The input driving part 400 may be mounted on a circuit board located in the peripheral region DM-NAA (see FIG. 2). The circuit board may be a flexible film such as a flexible printed circuit board, a printed circuit board, or a chip-on-film.

The input driving part 400 may supply a driving signal to a sensing electrode SN, and may sense a change in capacitance of the sensing electrode SN. The input driving part 400 may be configured with an integrated circuit (IC).

The main processor 500 may control all functions of the display device DD. For example, the main processor 500 may supply digital video data to the display driving part 200 so that the display panel DP (see FIG. 3) displays an image. For example, after receiving data from the input driving part 400 and determining input coordinates of a user, the main processor 500 may generate digital video data based on the input coordinates, or may execute an application indicated by an icon displayed in the input coordinates of the user. In addition, after receiving coordinate data from the touch input device 20 and determining input coordinates of the touch input device the main processor 500 may generate digital video data based on the input coordinates, or may execute an application indicated by an icon displayed in the input coordinates of the touch input device 20.

The communication part 600 may perform wired/wireless communication with an external device. For example, the communication part 600 may transmit/receive communication signals to/from a communication module 24 of the touch input device 20. The communication part 600 may receive, from the touch input device 20, coordinate data composed of a data code, and may provide the coordinate data to the main processor 500.

The touch input device 20 may include a camera 21, a piezoelectric sensor 22, a processor 23, a communication module 24, a memory 25, and a battery 26. For example, the touch input device 20 may be a smart pen that generates coordinate data through an optical method. However, this is an example, and embodiments of the inventive concept are not limited thereto.

The camera 21 may be located in front of the touch input device 20. The camera 21 may photograph the first pattern parts CPT, CPT-a, and CPT-aa, and the third pattern part PT-1 described above. The camera 21 may continuously photograph the first pattern parts CPT, CPT-a, and CPT-aa and the third pattern part PT-1 at the corresponding positions according to the movement of the touch input device 20. The camera 21 may provide the photographed image to the processor 23.

The piezoelectric sensor 22 may sense a pressure applied to the display device DD by the touch input device 20. The piezoelectric sensor 22 may provide pressure information of the touch input device 20 to the processor 23.

The processor 23 may receive, from the camera 21, images of the first pattern parts CPT, CPT-a, and CPT-aa and the third pattern part PT-1. The processor 23 may identify the first pattern part CPT including an infrared reactive material having a relatively great content, compared to the second pattern part APT. In addition, the processor 23 may identify the third pattern part PT-1 having a relatively great width, compared to the fourth pattern part PT-2. The processor 23 may combine position information about the first pattern parts CPT, CPT-a, and CPT-aa and the third pattern part PT-1, and may thus generate coordinate data. The processor 23 may transmit the generated coordinate data to the display device DD through the communication module 24.

The processor 23 may receive images of the first pattern parts CPT, CPT-a, and CPT-aa and the third pattern part PT-1, and may convert the first pattern parts CPT, CPT-a, and CPT-aa and the third pattern part PT-1 to one-to-one corresponding data codes, thereby rapidly generating coordinate data without complicated calculations and corrections. Accordingly, such a touch input system may reduce costs, decrease power consumption, and simplify a driving process.

The communication module 24 may perform wired/wireless communication with an external device. For example, the communication module 24 may transmit/receive communication signals to/from the communication part 600 of the display device DD. The communication module 24 may receive, from the processor 23, coordinate data composed of a data code, and may provide the coordinate data to the communication part 600.

The memory 25 may store data necessary for driving the touch input device 20. Because the touch input device 20 may convert the first pattern parts CPT, CPT-a, and CPT-aa and the third pattern part PT-1 to one-to-one corresponding data codes, and may immediately provide the coordinate data to the display device DD, the memory may have a relatively small capacity.

A display device according to some embodiments may include a sensing electrode located a pixel-defining film, a light-blocking pattern located on the sensing electrode, and a color filter located on the sensing electrode. The light-blocking pattern may include a first pattern part and a second pattern part having different optical densities with respect to light having a wavelength range of about 800 nm to about 1000 nm. The first pattern part may have a high absorbance with respect to light having a wavelength range of about 800 nm to about 1000 nm, and the second pattern part may allow light having a wavelength range of about 800 nm to about 1000 nm to pass therethrough. The first pattern part having a relatively high absorbance with respect to light having a wavelength range of about 800 nm to about 1000 nm may perform a function of a code including position information.

Alternatively, according to some embodiments, the light-blocking pattern may include a third pattern part and a fourth pattern part having different widths. The third pattern part and the fourth pattern part may each have an optical density (OD) of about 1 or more with respect to light having a wavelength range of about 800 nm to about 1000 nm. The sensing electrode may include a conductive line defining an electrode opening, and the third pattern part may overlap a first part of the conductive line, and the fourth pattern part may overlap a second part of the conductive line. The third pattern part having a relatively great width may perform a function of a code including position information. Color filters located on the sensing electrode may prevent or reduce instances of the light-blocking pattern located on the sensing electrode being viewed from the outside. Accordingly, a display device according to some embodiments may exhibit excellent reliability.

A display device according to some embodiments may include a light-blocking pattern on a sensing electrode to prevent or reduce instances of the light-blocking pattern being viewed from the outside, thereby exhibiting excellent reliability.

In the above, description has been made with reference to the example embodiments of the inventive concept, but those skilled in the art or those of ordinary skill in the relevant technical field may understand that various modifications and changes may be made to the inventive concept within the scope not departing from the spirit and the technology scope of the inventive concept described in the claims to be described later.

Therefore, the technical scope of the inventive concept is not limited to the contents described in the detailed description of the specification, but should be determined by the appended claims, and their equivalents.

What is claimed is:

1. A display device comprising:
a light-emitting element including a first electrode, a second electrode on the first electrode, and a light-emitting layer between the first electrode and the second electrode;
a pixel-defining film having a pixel opening exposing the first electrode;
a sensing electrode on the pixel-defining film;
a light-blocking pattern on the sensing electrode; and
a color filter on the sensing electrode,
wherein the light-blocking pattern comprises a first pattern part and a second pattern part, and
the first pattern part and the second pattern part have different optical densities (OD) with respect to first light.

2. The display device of claim 1, wherein the first light has a wavelength in a range of 800 nm to 1000 nm.

3. The display device of claim 2, wherein the first pattern part has an optical density of 1 or more with respect to light having a wavelength in a range of 800 nm to 1000 nm, and
the second pattern part has an optical density of less than 1 with respect to light having a wavelength range of 800 nm to 1000 nm.

4. The display device of claim 1, wherein the sensing electrode comprises a conductive line defining an electrode opening corresponding to the light-emitting element, and
the first pattern part is in contact with an upper surface and a side surface of a first part of the conductive line.

5. The display device of claim 4, wherein the first pattern part comprises a first region in contact with the upper surface and a second region in contact with the side surface, and
a first length of the first region in a normal direction of the upper surface is shorter than a second length of the second region in a normal direction of the side surface.

6. The display device of claim 4, wherein a width of the electrode opening is greater than a width of the pixel opening in a direction perpendicular to a thickness direction.

7. The display device of claim 1, wherein the second pattern part is on the first pattern part.

8. The display device of claim 1, wherein the first pattern part and the 20 second pattern part are spaced apart from each other in a cross-section view.

9. The display device of claim 1, wherein the first pattern part and the second pattern part each comprise an infrared reactive material that absorbs light having a wavelength range of 800 nm to 1000 nm.

10. The display device of claim 9, wherein a first content of the infrared reactive material with respect to a total weight of the first pattern part is greater than a second content of the infrared reactive material with respect to a total weight of the second pattern part.

11. The display device of claim 9, wherein the infrared reactive material comprises carbon.

12. The display device of claim 11, wherein the infrared reactive material further comprises silicon.

13. The display device of claim 1, wherein the light-emitting element comprises a first light-emitting element configured to emit first color-light, a second light-emitting element configured to emit second color-light different from the first color-light, and a third light-emitting element configured to emit third color-light different from the first color-light and the second color-light, and
the color filter comprises a first filter configured to transmit the first color-light, a second filter configured to transmit the second color-light, and a third filter configured to transmit the third color-light.

14. The display device of claim 13, wherein, on the first pattern part, at least two filters among the first filter, the second filter, and the third filter overlap each other.

15. A display device comprising:
a light-emitting element including a first electrode, a second electrode on the first electrode, and a light-emitting layer between the first electrode and the second electrode;
a pixel-defining film in which a pixel opening exposing the first electrode is defined;
a sensing electrode on the pixel-defining film;
a light-blocking pattern on the sensing electrode; and
a color filter on the sensing electrode, and overlapping the light-emitting element,
wherein the sensing electrode comprises a conductive line defining an electrode opening corresponding to the light-emitting element, and
the light-blocking pattern comprises a third pattern part overlapping a first part of the conductive line and having a first width, and a fourth pattern part overlapping a second part of the conductive line and having a second width smaller than the first width.

16. The display device of claim 15, wherein the light-blocking pattern has an optical density (OD) of 1 or more with respect to light having a wavelength in a range of 800 nm to 1000 nm.

17. The display device of claim 15, wherein, in a plan view, the third pattern part and the fourth pattern part each extend in a first extension direction and in a second extension direction crossing the first extension direction, and the first width and the second width are each parallel to any one of the first extension direction and the second extension direction.

18. The display device of claim 15, wherein a width of the pixel-defining film is greater than the second width in a direction perpendicular to a thickness direction.

19. The display device of claim 15, wherein the third pattern part and the fourth pattern part are spaced apart from each other in a cross-sectional view.

20. The display device of claim 15, wherein the display device is divided into a light-emitting region corresponding to the pixel opening and a non-light-emitting region surrounding the light-emitting region,
the light-emitting region comprises first light-emitting regions configured to emit first color-light, second light-emitting regions configured to emit second color-light different from the first color-light, and third light-emitting regions configured to emit third color-light different from the first color-light and the second color-light, and
on a cross-section, the third pattern part surrounds one first light-emitting region, two second light-emitting regions, and one third light-emitting region.

21. The display device of claim 20, wherein the third pattern part overlaps the non-light-emitting regions between the one first light-emitting region, the two second light-emitting regions, and the one third light-emitting region.

22. The display device of claim 15, wherein, in a plan view, the fourth pattern part extends from an edge of the third pattern part.

23. The display device of claim 15, wherein the third pattern part and the fourth pattern part each comprise an infrared reactive material that absorbs light having a wavelength range of 800 nm to 1000 nm.

24. The display device of claim 23, wherein the infrared reactive material comprises carbon.

25. The display device of claim 24, wherein the infrared reactive material further comprises silicon.
